(19) United States
(12) Patent Application Publication
(10) Pub. No.: US 2023/0137239 A1
(43) Pub. Date: May 4, 2023

(54) COOLING OF AN ELECTRONIC DEVICE

(71) Applicant: STMICROELECTRONICS (GRENOBLE 2) SAS, Grenoble (FR)

(72) Inventors: Younes BOUTALEB, Grenoble (FR); David KAIRE, Montaud (FR); Romain COFFY, Voiron (FR)

(73) Assignee: STMICROELECTRONICS (GRENOBLE 2) SAS, Grenoble (FR)

(21) Appl. No.: 17/970,336

(22) Filed: Oct. 20, 2022

(30) Foreign Application Priority Data
Oct. 29, 2021 (FR) 2111530

(51) Int. Cl. H01L 23/367; H01L 23/373; H01L 23/053; H01L 21/52

(52) U.S. Cl. CPC H01L 23/367; H01L 23/3736; H01L 23/053; H01L 21/52; H01L 2224/16225; H01L 24/16

(57) ABSTRACT

The present description concerns an electronic device comprising: an electronic chip comprising an active area on a first surface, and a second surface opposite to the first surface; a substrate, the first surface of said chip being mounted on a third surface of said substrate; and a thermally-conductive cover comprising a transverse portion extending at least above the second surface of said electronic chip, wherein the electronic device further comprises at least one thermally-conductive pillar coupling the second surface of the electronic chip to said transverse portion of said thermally-conductive cover.

### BACKGROUND

### Technical Field

The present disclosure generally concerns electronic systems and devices, and their protection and cooling means. The present disclosure in some embodiments applies to means for cooling an electronic device protected by a package.

### Description of the Related Art

Many techniques for cooling electronic systems and devices protected by a package are known. It is for example known to use packages adapted to dissipating the heat generated by the components and circuits of the electronic device or system.

It is desirable to be able to at least partly improve means for cooling the electronic devices protected by a package.

### BRIEF SUMMARY

An embodiment overcomes all or part of the disadvantages of known electronic device cooling means.

An embodiment provides an electronic device comprising:

an electronic chip comprising an active area on a first surface, and a second surface opposite to the first surface;

a substrate, the first surface of said chip being mounted on a third surface of said substrate; and

a thermally-conductive cover comprising a transverse portion extending at least above the second surface of said electronic chip, wherein the electronic device further comprises at least one thermally-conductive pillar coupling the second surface of the electronic chip to said transverse portion of said thermally-conductive cover.

According to an embodiment, said at least one thermally-conductive pillar is a metal pillar.

According to an embodiment, said at least one thermally-conductive pillar comprises a first copper portion.

According to an embodiment, said at least one thermally-conductive pillar comprises at least a second portion made of a metal solder alloy.

According to an embodiment, said at least one thermally-conductive pillar is surrounded by a first layer made of a first thermally-conductive material extending from said second surface of the electronic chip to said transverse portion of said thermally-conductive cover.

According to an embodiment, said first layer further covers at least a fourth lateral surface of said electronic chip.

According to an embodiment, said transverse portion of said cover having a first portion having a first thickness extending above the second surface of said electronic chip, and at least a second portion having a second thickness greater than the first thickness extending at the periphery of said electronic chip.

According to an embodiment, the second portion extends all the way to the level of the first surface of said electronic chip.

According to an embodiment, said second portion is coupled to said third surface of said substrate by at least one first thermally-conductive bar.

According to an embodiment, the cover further comprises at least one lateral portion surrounding the electronic chip, and at least one extension extending from the lateral portion of the cover to said fourth lateral surface of said electronic chip.

According to an embodiment, the space between said transverse portion of said cover and said at least one extension is filled with a second thermally-conductive material.

According to an embodiment, said extension is coupled to said third surface of said substrate by at least a second thermally-conductive bar.

According to an embodiment, the thermally-conductive cover is a metal cover.

According to an embodiment, said at least one extension comprises on its upper surface at least one groove.

An embodiment provides a method of manufacturing an electronic device comprising an electronic chip having an active area on a first surface, and a second surface opposite to the first surface, the method comprising the successive steps of:
forming at least one thermally-conductive pillar on said second surface of said electronic chip;
mounting said electronic chip on a third surface of a substrate, the first surface of the chip being on the side of the third surface of said substrate; and
arranging a thermally-conductive cover comprising a transverse portion extending above the first surface of said electronic chip, said transverse portion being in contact with said at least one thermally-conductive pillar.

According to an embodiment, said at least one thermally-conductive pillar comprises a first copper portion and at least a second portion made of a metal solder alloy.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 comprises a side cross-section view and a top cross-section view of an embodiment of an electronic device;

FIG. 2 comprises six side cross-section views illustrating steps of an implementation mode of the method of manufacturing the embodiment of FIG. 1;

FIG. 3 comprises a side cross-section view and a top cross-section view of another embodiment of an electronic device;

FIG. 4 shows a side cross-section view of another embodiment of an electronic device;

FIG. 5 shows a side cross-section view of another embodiment of an electronic device;

FIG. 6 shows a side cross-section view of another embodiment of an electronic device;

FIG. 7 shows a side cross-section view of another embodiment of an electronic device;

FIG. 8 shows a side cross-section view of another embodiment of an electronic device;

FIG. 9 shows a side cross-section view of another embodiment of an electronic device;

FIG. 10 shows a side cross-section view of an embodiment of an electronic device according to another aspect;

FIG. 11 shows a side cross-section view of another embodiment of an electronic device; and

FIG. 12 comprises three side cross-section views illustrating steps of an implementation mode of the method of manufacturing the embodiment of FIG. 10.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front,”, “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and in some embodiments within 5%.

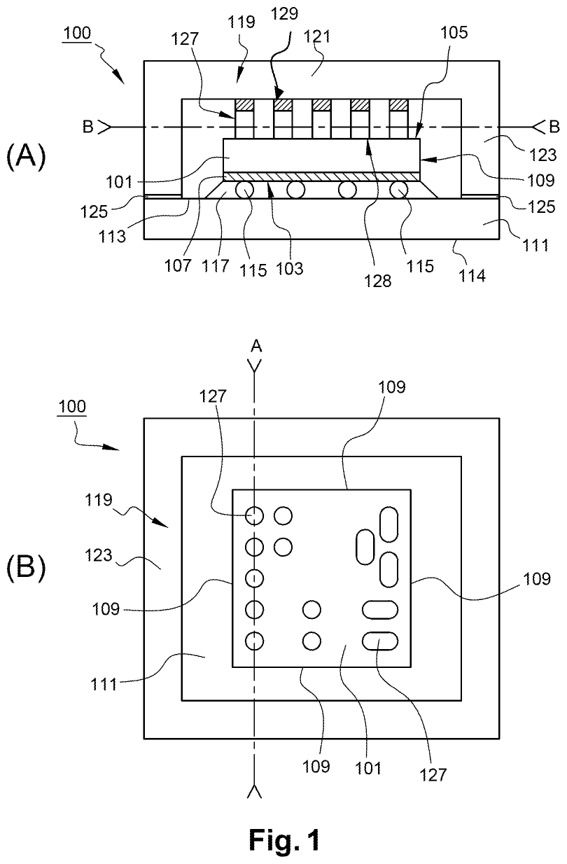

FIG. 1 comprises two cross-section views (A) and (B) illustrating an embodiment of an electronic device 100. View (A) is in some embodiments a side cross-section view of device 100 along the axis AA shown in view (B). View (B) is, in some embodiments, a top cross-section view of device 100 along the axis BB shown in view (A).

Electronic device 100 comprises an electronic chip 101 comprising one or a plurality of components (not shown in FIG. 1) formed inside and/or on top of a substrate plate, for example, a silicon substrate. Chip 101 comprises a surface 103 and a surface 105 opposite to surface 103. Chip 101 for example has a cuboid shape. On the side of surface 103 is the active area 107 of chip 101, shown by hatchings in FIG. 1. Here call active layer of an electronic chip the portion of the electronic chip having most of the electronic components of the chip and the electric contacts which enable the chip to be used formed therein. Chip 101 further comprises lateral surfaces 109.

Electronic device 100 further comprises a substrate 111 having chip 101 mounted thereon. Substrate 111 is for example a printed circuit board, a succession of conductive layers and of insulating layers forming metallization levels, a plate crossed by electrically-conductive vias, etc. More precisely, surface 103 of chip 101 is mounted on a surface 113 of substrate 111 via electric connectors 115 coupling electronic contacts of the active area 107 of chip 101 to electric contacts formed at the level of surface 113 of substrate 111. The contacts of active area 107 and of surface 113 are not shown in FIG. 1 for simplicity. Electric connectors 115 are, for example conductive balls or conductive bumps, for example solder balls. Electric connectors 115 are embedded in a filling material 117 enabling to protect them. This filling material 117 is an electrically-insulating material. These may for example be materials known under trade name XS8410-302SNS8AG or U8410-399F (Namics). Further, the substrate 111 may comprise contacts (not shown in FIG. 1) on its other surfaces, e.g., surface 114 that is opposite to surface 113, to allow the connection of electronic device 100 to other electronic devices. These contacts may be electrically coupled to other contacts via solder balls, not shown in FIG. 1.

Electronic device 100 further comprises a cover 119 made of a thermally-conductive material. According to an example, cover 119 is a metal cover, in some embodiments, made of copper. Cover 119 comprises a transverse portion 121 extending substantially parallel to the surfaces 103 and 105 of chip 101 and to surface 113 of substrate 111, and lateral portions 123 extending substantially parallel to surfaces 109 of chip 101. According to an example, transverse portion 121 and lateral portions 123 each are plates of substantially constant thickness, for example, having a thickness in the range from 0.3 mm to 1 mm, inclusive, for example, in the order of 0.5 mm. According to an example, cover 119 is made of one piece and comprises portions 121 and 123. according to an embodiment, portions 121 and 123 may be parts attached to one another to form cover 119, for example, attached together by gluing.

Cover 119 is arranged over chip 101 to protect the surfaces 105 and 109 of chip 101. Cover 119 is attached to surface 113 of substrate 111 through bonding, for example, via a glue layer 125 arranged between the end of the lateral portions 123 of cover 119 and surface 113 of substrate 111.

Electronic device 100 further comprises one or a plurality of, in some embodiments, a plurality of, thermally-conductive pillars 127 extending from surface 105 of chip 101 to the transverse portion 121 of cover 119. According to an embodiment, a first end 128 of each pillar 127 is in direct contact with surface 105, and a second end 129, opposite to the first end, is in direct contact with the transverse portion 121 of cover 119.

Pillars 127 are distributed on surface 105 of chip 101 (see view (B)). According to an embodiment, pillars 127 are concentrated in the areas of chip 101 generating the most heat.

According to an embodiment, pillar(s) 127 are metal pillars. According to an embodiment, pillar(s) 127 comprise at least one portion made of a first metal, for example, copper or an alloy comprising copper, and at least a second portion made of a second metal, for example, a metal alloy, for example, a metal alloy intended for soldering. According to an example, the first end 128 corresponding to the first portion of pillar 127, and the second end 129 corresponds to the second portion of pillar 127. A device 100 may comprise pillars 127 of different shapes. Pillars 127 may have a tubular shape with an oblong or even round cross-section (see view (B) of FIG. 1).

Substrate 111, cover 119, and pillar(s) 127 form the protection package of chip 101 in electronic device 100.

According to an example of embodiment, electronic device 100 has a length and a width in the range from 13 mm to 55 mm, inclusive, for example a length in the order of 45 mm and a width in the order of 45 mm, and a thickness in the range from 1.5 mm to 4 mm, inclusive, for example, in the order of 2.5 mm. For such an electronic device, chip 101 may have a length and a width in the range from 10 mm to 20 mm, inclusive, for example, a length in the order of 15 mm and a width in the order of 15 mm, and a thickness in the range from 150 mm to 400 mm, inclusive, for example, in the order of 300 mm. In this case, pillars 127 may have a width in the range from 30 to 100 μm, inclusive, for example in the order of 60 or 80 μm, and a height in the range from 50 to 120 μm, inclusive. An advantage of this embodiment is that it enables to efficiently remove the heat generated by chip 101 during its operation. In other words, the package formed by substrate 111, cover 119 and pillar(s) 127 enables to extract the heat from chip 101. Indeed, during its operation, chip 101 may generate heat, pillars 127 being thermally-conductive, they enable to guide the heat generated by chip 101 towards cover 119, which is itself thermally-conductive, to remove as much heat as possible to the outside of the electronic package.

Another advantage of this embodiment is that the pillar concentration may be increase at the level of hot spots of chip 101, that is, the areas of surface 103 generating the most heat. This is not true for a uniform layer made of a thermally-conductive material.

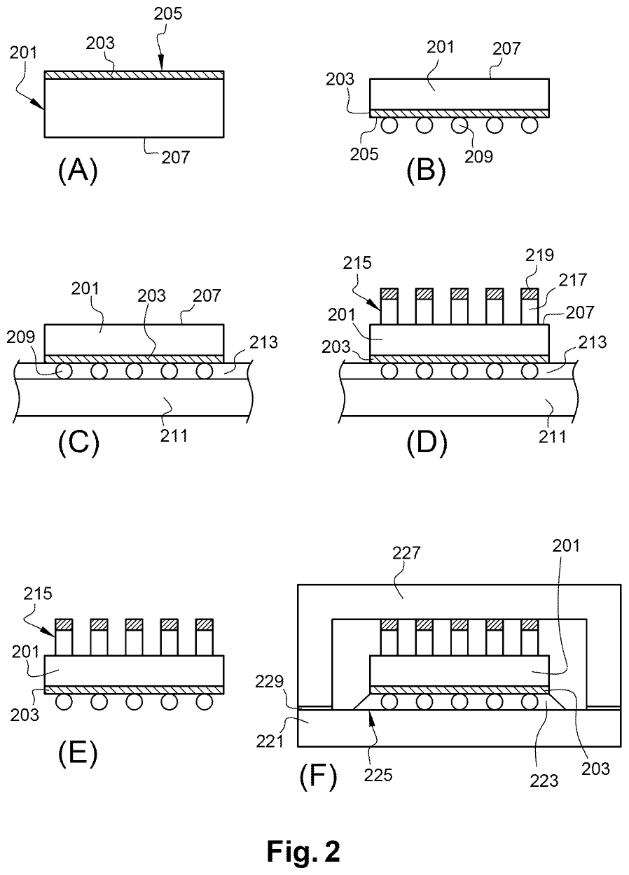

FIG. 2 comprises six cross-section views (A), (B), (C), (D), (E), and (F), each illustrating a step of an implementation mode of a method of manufacturing the device 100 described in relation with FIG. 1.

The steps illustrated in FIG. 2 are performed while the chips are still in a wafer. For simplification, only one chip 201 is shown in FIG. 2.

At the step of view (A), the different chips 201 comprise an active area 203 arranged on the side of a surface 205, opposite to a surface 207, at the wafer scale.

At the step of view (B), connectors 209 of the type of the connectors 115 of FIG. 1 are formed at the level of contacts of the active area 203 of chip 201. The wafer is then flipped so that its surface 207 is accessible. The wafer is then thinned so that its thickness is at a desired thickness.

At the step of view (C), wafer 201 is bonded to a temporary support 211 via a temporary bonding layer 213 arranged at the level of connectors 209.

At the step of view (D), one or a plurality of, in some embodiments a plurality of, thermally-conductive pillars 215 are formed at the level of the surface 207 of the different chips 201 in the wafer. According to an embodiment, a metal portion 217 is formed first, after which a second metal portion 219 is formed on top. For example, the pillars are formed by electrolytic deposition.

At the step of view (E), the temporary support is removed. The manufacturing of unit chips 201 is for example ended by a singulation step.

At the step of view (F), chip 201 is attached to a substrate 221 of the type of the substrate 111 of FIG. 1 via connectors 209. A filling material 223 is then arranged between the active area of chip 201 and a surface 225 of substrate 221.

Then, a cover 227 of the type of the cover 119 of FIG. 1 is arranged on chip 201. For this purpose, lateral portions of cover 227 are bonded, for example by gluing, to the surface 225 of substrate 221. The gluing is for example performed by deposition of a glue layer 229. According to an example, if cover 227 is formed of a plurality of parts glued together, cover 227 may be assembled around chip 201.

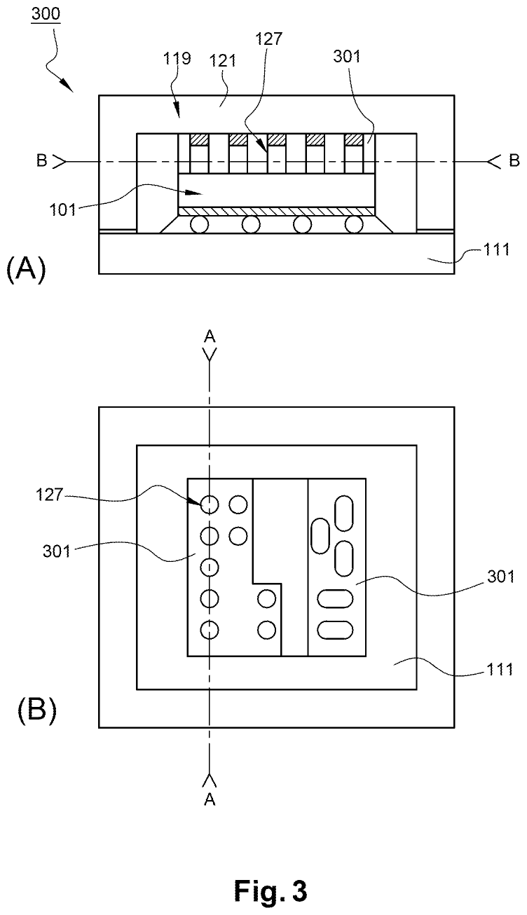

FIG. 3 comprises two cross-section views (A) and (B) illustrating an embodiment of an electronic device 300. View (A) is in some embodiments a side cross-section view of device 300 along the axis AA shown in view (B). View (B) is, in some embodiments, a top cross-section view of device 300 along the axis BB shown in view (A).

Further, electronic device 300 has elements common with the electronic device 100 described in relation with FIG. 1. These common elements are not described again in detail herein, and only the differences between devices 100 and 300 are highlighted.

Electronic device 300 differs from device 100 in that a layer 301 made of a thermally-conductive material is formed around pillar(s) 127. Layer 301 extends along the entire height of pillar(s) 127, that is, from the layer 105 of chip 101 all the way to the transverse portion 121 of cover 119. According to an embodiment, a lower surface of layer 301 is in direct contact with surface 105, and an upper surface, opposite to the lower surface, is in direct contact with the transverse portion 121 of cover 119.

According to an embodiment, layer 301 may extend over one or a plurality of portions (see view (B) of FIG. 3) of the surface 105 of chip 101 but may, according to a variant, extend over the entire surface 105 of chip 101. According to an example, layer 301 is formed at the level of one or a plurality of hot spots of chip 101.

As previously mentioned, layer 301 is made of a thermally-conductive material. According to an example, this material is selected by the group comprising: the material bearing reference SE4450 commercialized by Dow Corning, and the material bearing reference TC304 commercialized by Dow Corning.

An advantage of this embodiment is that layer 301 enables to improve the heat transfer from the chip to the outside of the package.

Device 300 further has the same advantages as those of the device 100 described in relation with FIG. 1.

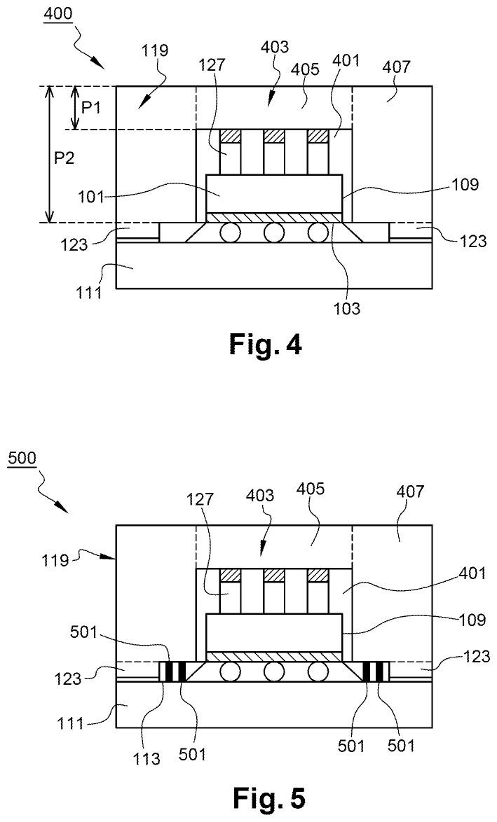

FIG. 4 is a side cross-section view illustrating an embodiment of an electronic device 400.

Electronic device 400 has elements common with the electronic device 300 described in relation with FIG. 3. These common elements are not described again in detail herein, and only the differences between devices 400 and 300 are highlighted.

Electronic device 400 differs from device 300 in that layer 301 is replaced with a layer 401 made of a thermally-conductive material formed around pillar(s) 127. Like layer 301, layer 401 extends all along the height of pillar(s) 127, that is, from the layer 105 of chip 101 to a transverse portion 403 of cover 119. Further, according to an embodiment, layer 401 further covers all or part of the lateral surfaces 109 of chip 101.

Further, like layer 301, layer 401 may extend over one or a plurality of portions (see view (B) of FIG. 5) of the surfaces 105 and 109 of chip 101 but may, according to a variant, extend all over surface 105 of chip 101 and over all the surfaces 109 of chip 101. According to an example, layer 401 is formed at the level of hot spots of chip 101.

As previously mentioned, layer 401 is made of a thermally-conductive material. According to an example, this material is selected from the group comprising: the material bearing reference SE4450 commercialized by Dow Corning, and the material bearing reference TC3040 commercialized by Dow Corning.

Electronic device 400 further differs from device 300 in that cover 119 comprises a transverse portion 403 different from the transverse portion 121 described in relation with FIG. 1. Transverse portion 403 comprises portions of different thicknesses, in some embodiments, transverse portion 403 comprises:
a portion 405 of thickness P1 extending above chip 101; and
at least a portion 407 of a thickness P2 extending around, that is, at the periphery of, chip 101.

According to an embodiment, thickness P1 is smaller than thickness P2. In practice, thickness P2 is large enough for portion 407 to extend at least all the way to the level of surface 103 of chip 101. Thereby, lateral surfaces 109, and more precisely the portions of layer 401 covering them, are in contact with portion 407 of the transverse portion 403 of cover 119. Thus, according to an embodiment, an upper surface of layer 401 is in direct contact with surface 105 and surfaces 109, and a lower surface, opposite to the upper surface, is in direct contact with the transverse portion 403 of cover 119.

An advantage of this embodiment is that layer 401 and portion 407 of the transverse portion 403 of cover 119 enable to remove the heat emitted from the lateral surfaces 109 of chip 101.

Device 400 further has the same advantages as those of the device 300 described in relation with FIG. 3.

FIG. 5 is a side cross-section view illustrating an embodiment of an electronic device 500.

Further, electronic device 500 has elements common with the electronic device 400 described in relation with FIG. 4. These common elements are not described again in detail herein, and only the differences between devices 400 and 500 are highlighted.

Electronic device 500 differs from device 400 in that device 500 comprises one or a plurality of, in some embodiments, a plurality of, thermally-conductive bars 501 arranged between portion 407 of the transverse portion 403 of cover 119 and surface 113 of substrate 111. In some embodiments, according to an embodiment, bar(s) 501 are in direct contact with portion 407 of the transverse portion 121 of cover 119 and with surface 113 of substrate 111.

According to an embodiment, thermally-conductive bar(s) 501 extend over all or part of surface 113. Bar(s) 501 have a width in the range from 50 μm to 100 μm, for example, in the order of 80 μm.

According to an embodiment, thermally-conductive bar(s) 501 are metal bars, for example, bars made of copper or of a metal alloy comprising copper.

An advantage of this embodiment is that bar(s) 501 enable to remove part of the heat released by chip 101 in substrate 111.

Device 500 further has the same advantages as those of the device 400 described in relation with FIG. 4.

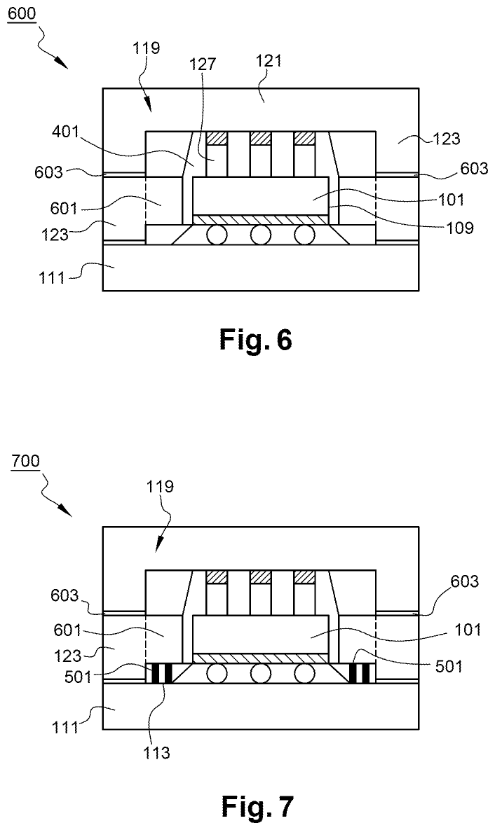

FIG. 6 is a side cross-section view illustrating an embodiment of an electronic device 600.

Further, electronic device 600 has elements common with the electronic device 100 described in relation with FIG. 1. These common elements are not described again in detail herein, and only the differences between devices 100 and 600 are highlighted.

Electronic device 600 differs from device 100 in that device 600 comprises layer 401 made of a thermally-conductive material described in relation with FIG. 4.

Electronic device 600 differs from device 100 in that device 600 further comprises one or a plurality of, in some embodiments a plurality of, extensions 601 at the level of the lateral portions 123 of cover 119. In some embodiments, extensions 601 extend from the lateral portions 123 of cover 119 to the lateral surfaces 109 of chip 101, and more precisely to the portions of layer 401 covering them. According to an example, extensions 601 have a thickness in the order of the thickness of chip 101. Extensions 601 may have a thickness greater than that of the chip. They may also have a smaller thickness but to the detriment of the heat dissipation effect.

According to an embodiment, extensions 601 are made of the same material as cover 119. Further, as described in relation with FIG. 1, cover 119 may be made of a single part comprising portions 121 and 123, and extensions 601, but according to a variant, portions 121 and 123 and extensions 601 may be parts attached to one another to form cover 119. These parts may be attached together by gluing, that is, for example, via one or a plurality of glue layers 603. It will be within the abilities of those skilled in the art to imagine a plurality of combinations of parts enabling to obtain the cover 119 of device 600.

An advantage of this embodiment is that the extensions 601 of cover 119 enable to remove the heat emitted from the lateral surfaces 109 of chip 101.

Device 600 further has the same advantages as those of the devices 100 described in relation with FIG. 1.

FIG. 7 is a side cross-section view illustrating an embodiment of an electronic device 700.

Further, electronic device 700 has elements common with the electronic device 600 described in relation with FIG. 6. These common elements are not described again in detail herein, and only the differences between devices 600 and 700 are highlighted.

Electronic device 700 differs from device 600 in that device 700 comprises one or a plurality of, in some embodiments a plurality of, thermally-conductive bars 501 as described in relation with FIG. 5. In device 700, bar(s) 501 are arranged between the extension(s) 601 of cover 119 and the surface 113 of substrate 111. In some embodiments, according to an embodiment, bar(s) 501 are in direct contact with the extension(s) 601 of cover 119 and with the surface 113 of substrate 111.

Device 700 has the same advantages as those of the devices 500 and 600 described in relation with FIGS. 5 and 6.

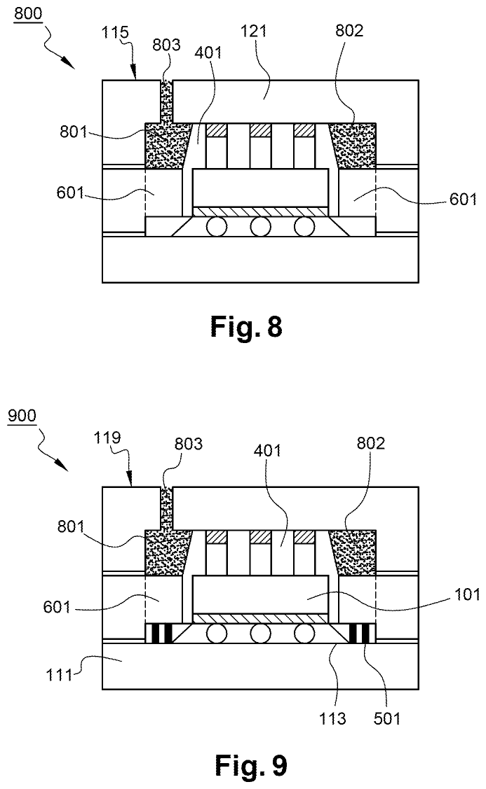

FIG. 8 is a side cross-section view illustrating an embodiment of an electronic device 800.

Further, electronic device 800 has elements common with the electronic device 600 described in relation with FIG. 6. These common elements are not described in detail again herein, and only the differences between devices 600 and 800 are highlighted.

Electronic device 800 differs from device 600 in that the space, or cavity, 802 formed between extensions 601 and the transverse portion 121 of cover 119 is filled with a thermally-conductive material 801. In some embodiments, material 801 is a material having a thermal conductivity greater than 2 W/mK, or even 3 W/mK. Material 801 is for example selected from the group comprising: the material known under trade name SE4450 of Dow Corning, and the material known under trade name TC3040 of Dow Corning. The use of materials known under trade name TIM is also possible.

According to an example of embodiment, material 801 is injected into space 802 via a cavity 803 formed through the transverse portion 121 of cover 119.

An advantage of this embodiment is that the presence of material 801 enables to improve the heat removal in cover 119.

Device 800 further has the same advantages as those of the device 600 described in relation with FIG. 6.

FIG. 9 is a side cross-section view illustrating an embodiment of an electronic device 900.

Further, electronic device 900 has elements common with the electronic device 800 described in relation with FIG. 8. These common elements are not described in detail again herein, and only the differences between devices 800 and 900 are highlighted.

Device 900 differs from device 800 in that device 900 comprises one or a plurality of, in some embodiments a plurality of, thermally-conductive bars 501 as described in relation with FIG. 5. In device 900, bar(s) 501 are arranged between the extension(s) 601 of cover 119 and the surface 113 of substrate 111. In some embodiments, according to an embodiment, bar(s) 501 are in direct contact with the extension(s) 601 of cover 119 and with the surface 113 of substrate 111.

Device 900 has the same advantages as those of the devices 500 and 800 described in relation with FIGS. 5 and 8.

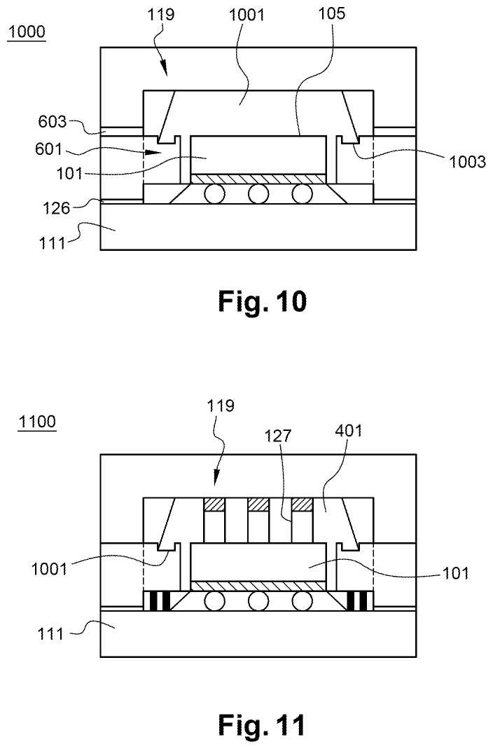

FIG. 10 is a side cross-section view illustrating an embodiment of an electronic device 1000 according to another aspect.

Electronic device 1000 has elements common with the electronic device 600 described in relation with FIG. 6. These common elements are not described again herein, and only the differences between devices 1000 and 600 are highlighted.

Device 1000 differs from device 600 in that device 100 comprises no thermally-conductive pillar 127 between the surface 105 of chip 101 and the transverse portion of metal cover 119.

Instead, device 1000 comprises a layer 1001 made of a thermally-conductive material. Layer 1001 extends from the surface 105 of chip 101 to the transverse portion 121 of cover 119. In some embodiments, according to an embodiment, a lower surface of layer 1001 is in direct contact with surface 105, and an upper surface, opposite to the lower surface, is in direct contact with the transverse portion 121 of cover 119. According to an embodiment, layer 1001 may extend over the entire surface 105 or over one or a plurality of portions of the surface 105 of chip 101, as described for layer 301 in relation with FIG. 3. According to an example, layer 1001 is formed at the level of one or a plurality of hot spots of chip 101. Further, like the layer 401 described in relation with FIG. 4, layer 1001 may further cover all or part of the lateral surfaces 109 of chip 101. According to an example, layer 1001 is made of a material selected from the group comprising: the material bearing reference SE4450 commercialized by Dow Corning, and the material bearing reference TC3040 commercialized by Dow Corning.

Device 1000 further differs from device 600 in that the extension(s) 601 of cover 119 of device 1000 comprise at least one groove 1003, or trench 1003, surrounding chip 101. In some embodiments, groove 10003 is formed from an upper surface of extension 601, for example, a surface of the extension directed towards the transverse portion of cover 119. Groove 1003 is for example placed at a distance from chip 101 in the range from 500 μm to 2 mm, for example, in the order of 1 mm. According to an example, the groove has a depth in the range from 30 μm to 150 μm, for example, in the order of 70 μm, and a width in the range from 500 μm to 1.5 μm, for example in the order of 1 mm.

According to an alternative embodiment, extensions 601 may comprise more than one groove 1003, for example grooves 1003 parallel and/or concentric to one another.

An advantage of this embodiment is that said groove enables to slow down, or even to prevent, the migration of layer 1001 during the chip operation.

FIG. 11 is a side cross-section view illustrating an embodiment of an electronic device 1100 according to another aspect.

Further, electronic device 1100 has elements common with the electronic device 1000 described in relation with FIG. 10. These common elements are not described in detail again herein, and only the differences between devices 1100 and 1000 are highlighted.

Device 1100 differs from device 1000 in that device 1100 does not comprise layer 1001 but the layer 401 described in relation with FIG. 4 and the pillars 127 described in relation with FIG. 1.

Device 1100 has the same advantages as those of the devices 600 and 1000 described in relation with FIGS. 6 and 10.

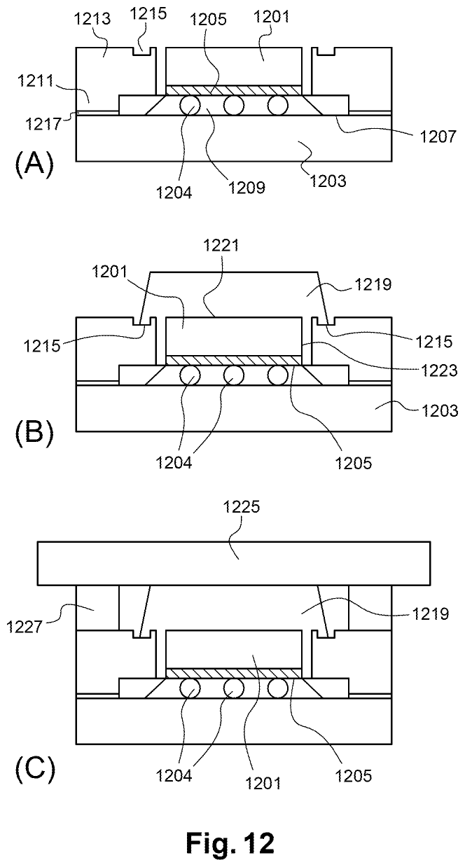

FIG. 12 comprises three cross-section views (A), (B), and (C) each illustrating a step of an implementation mode of a method of manufacturing the device 1000 described in relation with FIG. 10. An implementation mode of a method of manufacturing the device 1100 described in relation with FIG. 11 will be deduced from the combination of the manufacturing method described in relation with FIG. 2 and of the manufacturing method described hereafter.

At the step of view (A), a chip 1201 has been mounted on a substrate 1203. For this purpose, connectors 1204 have been formed on a surface 1205 corresponding to the active area of chip 1201. Connectors 1204 have been embedded in a filling material 1209 at the upper surface 1207 of substrate 1203.

At the step of view (A), a first portion of a thermally-conductive cover of the type of the cover 119 described in relation with FIG. 10 is arranged around chip 1201. The portion of the cover comprises lateral portions 1211 of the cover, of the type of the portions 123 described in relation with FIG. 1, and extensions 1213, of the type of the extensions 601 described in relation with FIG. 6. Like extensions 601, extensions 1213 comprise one or a plurality of grooves 1215 formed from an upper surface of extensions 1213. According to an example, grooves 1215 are formed in extensions 1215 at the step of view (A) or are preformed. According to an example, this portion of the cover is made of a single block. According to an embodiment, this portion of the cover is made of a plurality of portions assembled together, for example, by gluing.

The portion of the cover is attached to the upper portion 1207 of substrate 1203, for example, via a glue layer 1217.

At the step of view (B), a layer 1219 made of a thermally-conductive material is formed on all or part of a surface 1221 of chip 1201, opposite to surface 1205. Layer 1219 is deposited all the way to the groove 1215 of extensions 1213. Layer 1219 may for example cover all or part of the lateral surfaces 1223 of chip 1201. Layer 1219 is for example made of a material selected from the group comprising: the material bearing reference SE4450 commercialized by Dow Corning, and the material bearing reference TC3040 commercialized by Dow Corning.

At the step of view (C), the last portion of the cover is formed on chip 1201. According to the example illustrated in view (C), the last portion of the cover is a lateral portion 1225 of the type of the lateral portion 121 described in relation with FIG. 1. Portion 1225 is for example a plate of material bonded on layer 1219 via a glue layer 1227 at the previously-attached lateral portions 1211 of the cover. According to an example, layer 1219 and glue layer 1227 have a substantially equal thickness.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

Electronic device (100; 300; 400; 500; 600; 700; 800; 900) may be summarized as including an electronic chip (101) including an active area (107) on a first surface (103) and a second surface (105) opposite to the first surface (103); a substrate (111), the first surface (103) of said chip (101) being mounted on a third surface (113) of said substrate (111); and a thermally-conductive cover (119) including a transverse portion (121; 403) extending at least above the second surface (105) of said electronic chip (101), wherein the electronic device (100; 300; 400; 500; 600; 700; 800; 900) further includes at least one thermally-conductive pillar (127) coupling the second surface (105) of the electronic chip (101) to said transverse portion (121; 403) of said thermally-conductive cover (119).

Said at least one thermally-conductive pillar (127) may be a metal pillar.

Said at least one thermally-conductive pillar (127) may include a first copper portion.

Said at least one thermally-conductive pillar (127) may include at least a second portion made of a metal solder alloy.

Said at least one thermally-conductive pillar (127) may be surrounded by a first layer (301; 401) made of a first thermally-conductive material extending from said second surface (105) of the electronic chip (101) to said transverse portion (121; 403) of said thermally-conductive cover (119).

Said first layer (401) may further cover at least a fourth lateral surface (109) of said electronic chip (101).

Said transverse portion (403) of said cover (119) may have a first portion (405) having a first thickness (P1) extending above the second surface (105) of said electronic chip (101), and at least a second portion (407) having a second thickness (P2) greater than the first thickness (P1) extending at the periphery of said electronic chip (101).

The second portion (407) may extend all the way to the level of the first surface (103) of said electronic chip (101).

Said second portion (407) may be coupled to said third surface (113) of said substrate (111) by at least one first thermally-conductive bar (501).

The cover (119) may further include at least one lateral portion (123) surrounding the electronic chip (101), and at least one extension (601) extending from the lateral portion (123) of the cover (119) to said fourth lateral surface (109) of said electronic chip (101).

The space (802) between said transverse portion (121) of said cover (119) and said at least one extension (601) may be filled with a second thermally-conductive material (801).

Said extension (801) may be coupled to said third surface (113) of said substrate (111) by at least a second thermally-conductive bar (501).

The thermally-conductive cover (119) may be a metal cover.

Said at least one extension (601) may include on its upper surface at least one groove (1003).

Method of manufacturing an electronic device may be summarized as including an electronic chip (201) having an active area (203) on a first surface (205), and a second surface (207) opposite to the first surface (205), the method including the successive steps of forming at least one thermally-conductive pillar (215) on said second surface (207) of said electronic chip (201); mounting said electronic chip (201) on a third surface (225) of a substrate (221), the first surface (205) of the chip (201) being on the side of the third surface (225) of said substrate (221); and arranging a thermally-conductive cover (227) including a transverse portion extending above the second surface (207) of said electronic chip (201), said transverse portion being in contact with said at least one thermally-conductive pillar (127).

Said at least one thermally-conductive pillar (215) may include a first copper portion and at least a second portion made of a metal solder alloy.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
an electronic chip comprising a first surface and a second surface opposite to the first surface, the first surface including an active area;
a substrate having a third surface, the first surface of the electronic chip mounted on the third surface of the substrate;
a thermally-conductive cover comprising a transverse portion at least partially over the second surface of the electronic chip; and
at least one thermally-conductive pillar coupled between the second surface of the electronic chip and the transverse portion of the thermally-conductive cover.

2. The device according to claim 1, wherein the at least one thermally-conductive pillar includes a metal pillar.

3. The device according to claim 1, wherein a thermally-conductive pillar of the at least one thermally-conductive pillar includes a first portion and a second portion, the first portion of the thermally-conductive pillar being copper, and the second portion of the thermally-conductive pillar being a conductive material different from copper.

4. The device according to claim 1, wherein a thermally-conductive pillar of the at least one thermally-conductive pillar includes a first portion and a second portion, the second portion of the thermally-conductive pillar being a metal solder alloy, and the first portion of the thermally-conductive pillar being a conductive material different from the metal solder alloy of the second portion.

5. The device according to claim 1, comprising a first layer of a first thermally-conductive material that surrounds the at least one thermally-conductive pillar, the first layer extending from the second surface of the electronic chip to the transverse portion of the thermally-conductive cover.

6. The device according to claim 5, wherein the first layer covers a lateral surface of the electronic chip.

7. The device according to claim 1, wherein the transverse portion of the thermally-conductive cover has a first portion and a second portion, the first portion of the thermally-conductive cover having a first thickness, and extending over the second surface of the electronic chip, and the second portion of the thermally-conductive cover having a second thickness greater than the first thickness and extending at a periphery of the electronic chip.

8. The device according to claim 7, wherein the second portion of the thermally-conductive cover extends all the way to a level of the first surface of the electronic chip.

9. The device according to claim 8, wherein the second portion of the thermally-conductive cover is coupled to the third surface of the substrate by at least one first thermally-conductive bar.

10. The device according to claim 1, wherein the thermally-conductive cover further comprises:
at least one lateral portion surrounding the electronic chip; and
at least one extension portion extending from the at least one lateral portion of the thermally-conductive cover to a lateral surface of the electronic chip.

11. The device according to claim 10, wherein a space between the transverse portion of the thermally-conductive cover and the at least one extension portion is filled with a second thermally-conductive material.

12. The device according to claim 10, wherein the at least one extension portion is each coupled to the third surface of the substrate by at least a second thermally-conductive bar.

13. The device according to claim 1, wherein the thermally-conductive cover is metal.

14. The device according to claim 10, wherein an extension portion of the at least one extension portion comprises on its upper surface at least one groove.

15. A method of manufacturing an electronic device, the method comprising:
forming at least one thermally-conductive pillar on a second surface of an electronic chip that is opposite to a first surface of the electronic chip, the first surface having an active area;
mounting the electronic chip on a third surface of a substrate, the first surface of the electronic chip facing the third surface of the substrate; and
arranging a thermally-conductive cover over the electronic chip, a thermally-conductive cover including a transverse portion facing the second surface of the electronic chip, the transverse portion being in contact with the at least one thermally-conductive pillar.

16. The method according to claim 15, wherein the at least one thermally-conductive pillar each comprises a first portion of copper and a second portion of a metal solder alloy.

17. A semiconductor package, comprising:
a die having a first surface and a second surface opposite to the first surface;
a substrate coupled to the die, the first surface of the die facing the substrate;
a thermally-conductive cover; and
a plurality of a thermally-conductive pillar each including a first end coupled to the second surface of the die and a second end coupled to the thermally-conductive cover.

18. The package according to claim 17, comprising electrical connection elements coupled between the first surface of the die and the substrate.

19. The package according to claim 17, wherein a thermally-conductive pillar of the at least one thermally-conductive pillar includes a first portion of copper and a second portion of a metal solder alloy.

20. The package according to claim 17, wherein the thermally-conductive cover is coupled to the substrate through a coupling layer.
